(19) United States
(12) Patent Application Publication
(10) Pub. No.: US 2026/0309796 A1
(43) Pub. Date: Oct. 8, 2026

(54) ENERGY MANAGEMENT SYSTEM

(71) Applicant: Enphase Energy, Inc., Fremont, CA (US)

(72) Inventor: Jonathan List EHLMANN, Austin, TX (US)

(21) Appl. No.: 19/483,463

(22) PCT Filed: Apr. 18, 2024
(86) PCT No.: PCT/US2024/025090

§ 371 Date: Nov. 11, 2025

Related U.S. Application Data
(60) Provisional application No. 63/466,519, filed on May 15, 2023.

(51) Int. Cl. G01R 31/389; G01R 31/3842; G01R 31/392; G01R 31/396; H02J 3/38; H02J 101/24

(52) U.S. Cl. CPC G01R 31/389; G01R 31/3842; G01R 31/392; G01R 31/396; H02J 3/381; H02J 2101/24

(57) ABSTRACT

A method for taking EIS measurements in a storage system is provided herein. For example, the method can comprise performing EIS on a first battery in a storage system and providing power at a varying frequency to the first battery from a second battery connected to the first battery to maintain the first battery at a steady state.

### BACKGROUND

### 1. Field of the Disclosure

Embodiments of the present disclosure generally relate to energy management systems and, more particularly, to methods and apparatus that use electrochemical impedance spectroscopy (EIS) in battery systems.

### 2. Description of the Related Art

Energy management systems are known. For example, energy management systems can, typically, comprise one or more photovoltaics, a microinverter, and a storage system, which can comprise one or more batteries and a battery management unit/system (BMU/BMS) that is configured to control operation of the one or more batteries.

EIS is a non-destructive test to gain insight to battery electro-chemistry over varying conditions and a lifetime of the battery. For example, with EIS measurement, impedance measurements can be taken across a frequency range, e.g., from about 50 mHz (as in thousandths of a hertz, e.g., very low frequency) to about 20 KHz. For example, the impedance measurements can be taken by perturbing a DC operating current and/or voltage and by measuring a resulting small-signal current and/or voltage. The perturbation can be, for example, a sinusoidal wave at differing frequencies, a chirp signal, step, and/or an induced or naturally-present noise (e.g., from converter operation with varying a load). Traditional AC analysis can be difficult to perform when the impedance measurements are taken at relatively low frequencies, e.g., 50 mHz frequency (a period of 20 seconds), because the AC system may not operate in a linear, time-invariant manner. Also, a voltage in a battery can sometimes take hours to settle after a disturbance occurs, which can be referred to as a battery relaxation voltage. With such long time constants, keeping the battery under constant (or zero) charging/discharging requires repeated and accurate measurements.

Moreover, when a storage system comprises multiple batteries, one battery can be held under constant conditions, while the remaining batteries in the storage system meet operational demands. Unfortunately, EIS measurements may be interrupted if the operational demands of the storage system cannot be met without participation of the battery under EIS test. For EIS measurements, energy must be exchanged with the battery under test. For example, the energy can be sourced from one or more capacitors and/or inductors in the circuit, another battery, or from a power source that the battery is attached to (e.g., a grid). With such long time-constants, the capacitors and inductors in the circuit may not have enough energy storage to operate at low frequencies, and using the grid can provide the necessary power, but the perturbations can inject frequencies onto the grid, which may not be harmonic and is undesirable. Accordingly, if available, sourcing the battery under test with energy from another battery would prove advantageous.

Therefore, described herein are improved methods and apparatus that use electrochemical impedance spectroscopy (EIS) in battery systems.

### SUMMARY

In accordance with some aspects of the present disclosure, a method for taking EIS measurements in a storage system comprises performing EIS on a first battery in a storage system and providing power at a varying frequency to the first battery from a second battery connected to the first battery to maintain the first battery at a steady state.

In accordance with some aspects of the present disclosure, a non-transitory computer readable storage medium has instructions stored thereon that when executed by a processor perform a method for taking EIS measurements in a storage system. The method comprises performing EIS on a first battery in a storage system and providing power at a varying frequency to the first battery from a second battery connected to the first battery to maintain the first battery at a steady state.

In accordance with some aspects of the present disclosure, an energy management system comprises a controller configured to perform EIS on a first battery in a storage system and provide power at a varying frequency to the first battery from a second battery connected to the first battery to maintain the first battery at a steady state.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system, in accordance with at least some embodiments of the present disclosure;

FIG. 3 is a schematic diagram of an electrical circuit, in accordance with at least some embodiments of the present disclosure;

FIG. 4 is a schematic diagram of an electrical circuit, in accordance with at least some embodiments of the present disclosure;

FIG. 5 is a schematic diagram of an electrical circuit, in accordance with at least some embodiments of the present disclosure;

FIG. 6 is a schematic diagram of an electrical circuit, in accordance with at least some embodiments of the present disclosure;

FIG. 7 is a schematic diagram of an electrical circuit, in accordance with at least some embodiments of the present disclosure;

FIG. 8 is a flowchart of a method for taking EIS measurements in a storage system, in accordance with at least some embodiments of the present disclosure; and

FIG. 9 is a flowchart of a method for taking EIS measurements in a storage system, in accordance with at least some embodiments of the present disclosure.

### DETAILED DESCRIPTION

In accordance with the present disclosure, described herein are improved methods and apparatus that use electrochemical impedance spectroscopy (EIS) in battery systems. For example, a method for managing an energy management system can comprise performing EIS on a first battery in a storage system, Next, the method can comprise providing power at a varying frequency to the first battery from a second battery connected to the first battery to maintain the first battery at a steady state. Next, the method can comprise if other batteries in the system compensate for the change in operation of the battery under EIS measurement. The inventive concepts described herein provide an integrated battery test lab into a storage system using EIS. For example, data provided by EIS can give insight into subtle changes of battery electrochemistry over changing operational conditions and over the lifetime of the battery. The data, both directly and indirectly, can lead to better estimates of battery state of charge (SoC) and battery state of health (SoH). Additionally, the data becomes an even more valuable aggregate by creating a distributed, long-term battery test lab for one or more batteries in a storage system batteries, which can report data back to a controller (gateway) to determine settings for a first-based principles optimization engine through interactive user feedback in an iterative manner. Compared to conventional methods and apparatus described above, the methods and apparatus described herein can provide a better understanding of a mission profile of field-deployed batteries, improved modelling of battery electrochemistry, improved charging, balancing, SoC, and SoH algorithms, and improvements in battery cell construction and electrochemistry.

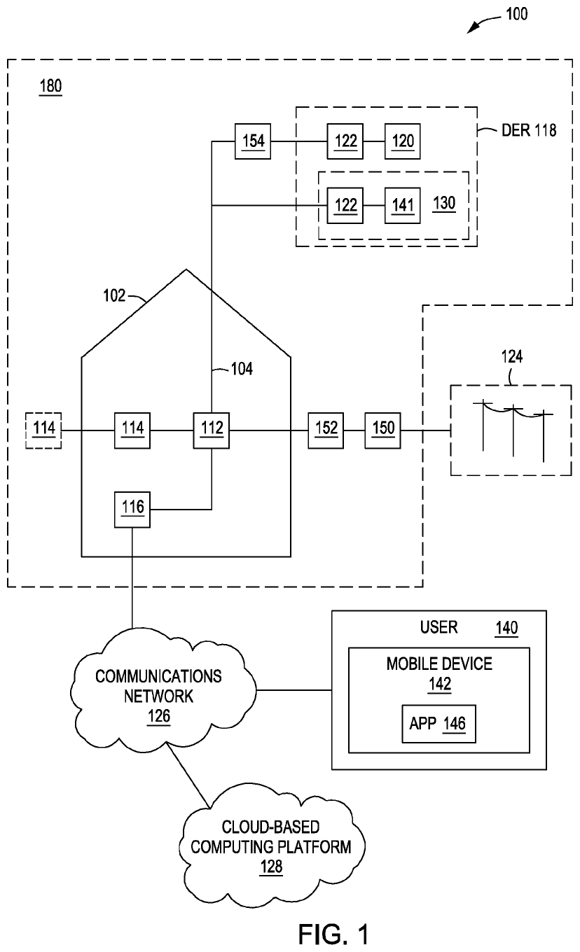

FIG. 1 is a block diagram of an energy management system (e.g., power conversion system, system 100) in accordance with one or more embodiments of the present disclosure. The diagram of FIG. 1 only portrays one variation of the myriad of possible system configurations. The present disclosure can function in a variety of environments and systems.

The system 100 comprises a structure 102 (e.g., a user's structure), such as a residential home, commercial building, or separate mounting structure, having an associated DER 118 (distributed energy resource). The DER 118 is situated external to the structure 102. For example, the DER 118 may be located on the roof of the structure 102 or can be part of a solar farm. The structure 102 comprises one or more loads and/or energy storage devices 114 (e.g., appliances, electric hot water heaters, thermostats/detectors, boilers, electric vehicle supply equipment (EVSE), EVs, water pumps, and the like), which can be located within or outside the structure 102, and a DER controller 116, each coupled to a load center 112. Although the energy storage devices 114, the DER controller 116, and the load center 112 are depicted as being located within the structure 102, one or more of these may be located external to the structure 102.

The load center 112 is coupled to the DER 118 by an AC bus 104 and is further coupled, via a meter 152 and optionally a MID 150 (microgrid interconnect device), to a grid 124 (e.g., a commercial/utility power grid). The structure 102, the energy storage devices 114, DER controller 116, DER 118, load center 112, generation meter 154, the meter 152, and the MID 150 are part of a microgrid 180. It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122. For example, the DER 118 may comprise a plurality of RESs 120 coupled to a plurality of power conditioners 122 in a one-to-one correspondence (or two-to-one). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one correspondence, where each pair of power conditioner 122 and a corresponding battery may be referred to as an AC battery 141.

The power conditioners 122 invert the generated DC power from the plurality of RESs 120 and/or the AC battery 141 to AC power that is grid-compliant and couple the generated AC power to the grid 124 via the load center 112. The generated AC power may be additionally or alternatively coupled via the load center 112 to the one or more loads (e.g., EV, EVSE) and/or the energy storage devices 114. In addition, the power conditioners 122 that are coupled to the AC batteries convert AC power from the AC bus 104 to DC power for charging the AC batteries. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway that receives data (e.g., alarms, messages, operating data, performance data, and the like) from the power conditioners 122 and communicates the data and/or other information via the communications network 126 to a cloud-based computing platform 128, which can be configured to execute one or more application software, e.g., a grid connectivity control application, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application) for performing one or more of the functions described herein. For example, the DER controller 116 can include a memory (e.g., a non-transitory computer readable storage medium) having stored thereon instructions that when executed by a processor perform a method for managing an energy management system (e.g., taking EIS measurements of a battery, as described in greater detail below).

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kWh) and, in some embodiments, reactive power flow (kVAR). The generation meter 154 may communicate the measured values to the DER controller 116, for example using PLC, other types of wired communications, or wireless communication. Additionally, battery charge/discharge values are received through other networking protocols from the battery 130.

The meter 152 may be any suitable energy meter that measures the energy consumed by the microgrid 180, such as a net-metering meter, a bi-directional meter that measures energy imported from the grid 124 and well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kWh), reactive power flow (kVAR), grid frequency, and grid voltage. The meter 152 measures power flows independently of MID state, i.e., when MID is closed and DER's are connected to the grid and when MID is open and DER's are isolated from the grid.

The MID 150, which may also be referred to as an island interconnect device (IID), connects/disconnects the microgrid 180 to/from the grid 124. The MID 150 comprises a disconnect component (e.g., a contactor or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication), and based on the received information (inputs), the DER controller 116 determines when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly, where the disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, or the like) communicably coupled by wireless means to the communications network 126. The mobile device 142 has a CPU, support circuits, and memory, and has one or more applications (e.g., a grid connectivity control application (an application 146)) installed thereon for controlling the connectivity with the grid 124 as described herein. The mobile device 142 may run on commercially available operating systems, such as IOS, ANDROID, and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, the scenarios below, listed in order of priority, will be managed differently. Based on the desired action as entered by the user 140, the corresponding instructions are communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

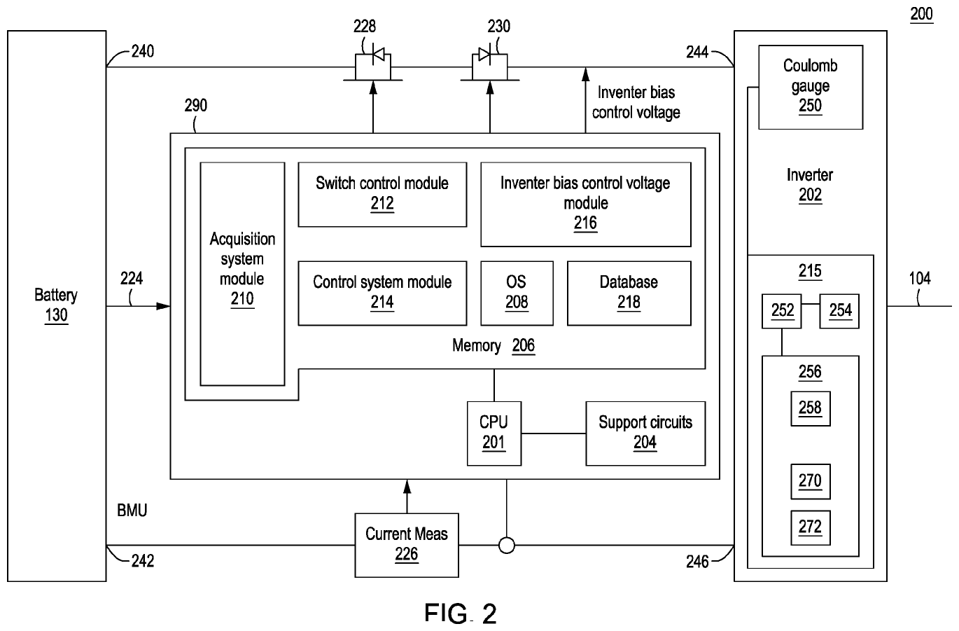

A storage system configured for use with an energy management system, such as the Enphase® Energy System, is described herein. For example, FIG. 2 is a block diagram of an AC battery system 200 (e.g., a storage system) in accordance with one or more embodiments of the present disclosure.

The AC battery system 200 comprises a BMU 290 coupled to a battery (e.g., the battery 130) and one or more power converters 202 (e.g., the power conditioners 122). In at least some embodiments, the battery 130 can comprise a plurality of cells (not shown) and the one or more power converters 202 can comprise four embedded converters (e.g., four embedded microinverters). In at least some embodiments, the battery 130 can be the IQ Battery 3 (or the IQ Battery 10) and the microinverters can be the IQ8X-BAT microinverters, both available from Enphase®. A pair of metal-oxide-semiconductor field-effect transistors (MOSFETs) switches—switches 228 and 230—are coupled in series between a first terminal 240 of the battery 130 and a first terminal 244 of the power converter such that the body diode cathode terminal of the switch 228 is coupled to the first terminal 240 of the battery 130 and the body diode cathode terminal of the switch 230 is coupled to the first terminal 244 of the one or more power converters 202. The gate terminals of the switches 228 and 230 are coupled to the BMU 290.

A second terminal 242 of the battery 130 is coupled to a second terminal 246 of the one or more power converters 202 via a current measurement module 226 which measures the current flowing between the battery 130 and the one or more power converters 202.

The BMU 290 is coupled to the current measurement module 226 for receiving information on the measured current, and also receives an input 224 from the battery 130 indicating the battery cell voltage and temperature. The BMU 290 is coupled to the gate terminals of each of the switches 228 and 230 for driving the switch 228 to control battery discharge and driving the switch 230 to control battery charge as described herein. The BMU 290 is also coupled across the first terminal 244 and the second terminal 246 for providing an inverter bias control voltage (which may also be referred to as a bias control voltage) to the one or more power converters 202.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 130 to the DC to AC converter 303 through the body diode of the switch 230. When the switch 228 is inactive while the switch 230 is active, battery charge is enabled to allow current flow from the one or more power converters 202 to the battery 130 through the body diode of the switch 228. When both switches 228 and 230 are active, the system is in a normal mode where the battery 130 can be charged or discharged.

The BMU 290 comprises support circuits 204 and a memory 206 (e.g., non-transitory computer readable storage medium), each coupled to a CPU 201 (central processing unit). The CPU 201 may comprise one or more processors, microprocessors, microcontrollers and combinations thereof configured to execute non-transient software instructions to perform various tasks in accordance with embodiments of the present disclosure. The CPU 201 may additionally or alternatively include one or more application specific integrated circuits (ASICs). In some embodiments, the CPU 201 may be a microcontroller comprising internal memory for storing controller firmware that, when executed, provides the controller functionality described herein. The BMU 290 may be implemented using a general purpose computer that, when executing particular software, becomes a specific purpose computer for performing various embodiments of the present disclosure.

The support circuits 204 are well known circuits used to promote functionality of the CPU 201. Such circuits include, but are not limited to, a cache, power supplies, clock circuits, buses, input/output (I/O) circuits, and the like. The BMU 290 may be implemented using a general purpose computer that, when executing particular software, becomes a specific purpose computer for performing various embodiments of the present disclosure. In one or more embodiments, the CPU 201 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores the OS 208 (operating system), if necessary, of the inverter controller 215 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 201 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 290 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the cell voltage and temperature information from the battery 130 via the input 224, obtains the current measurements provided by the current measurement module 226, and provides the cell voltage, cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SoC) analysis (e.g., coulomb counter 250 (or coulomb gauge) for determining current flow and utilizing the current flow in estimating the battery SoC; synchronizing estimated SoC values to battery voltages (such as setting SoC to an upper bound, such as 100%, at maximum battery voltage; setting SoC to a lower bound, such as 0%, at a minimum battery voltage); turning off SoC if the power conditioners 122 never drives the battery 130 to these limits; and the like), balancing (e.g., autonomously balancing the charge across all cells of a battery to be equal, which may be done at the end of charge, at the end of discharge, or in some embodiments both at the end of charge and the end of discharge). By establishing upper and lower estimated SoC bounds based on battery end of charge and end of discharge, respectively, and tracking the current flow and cell voltage (i.e., battery voltage) between these events, the BMU 290 determines the estimated SoC.

An inverter controller 215 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The DER controller 116 may be implemented using a general purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The DER controller 116 may be implemented using a general purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258 (operating system), if necessary, of the inverter controller 215 that can be supported by the CPU capabilities. In some embodiments, the OS 258 may be one of a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 290 communicates with the DER controller 116 to perform balancing of the batteries (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion.

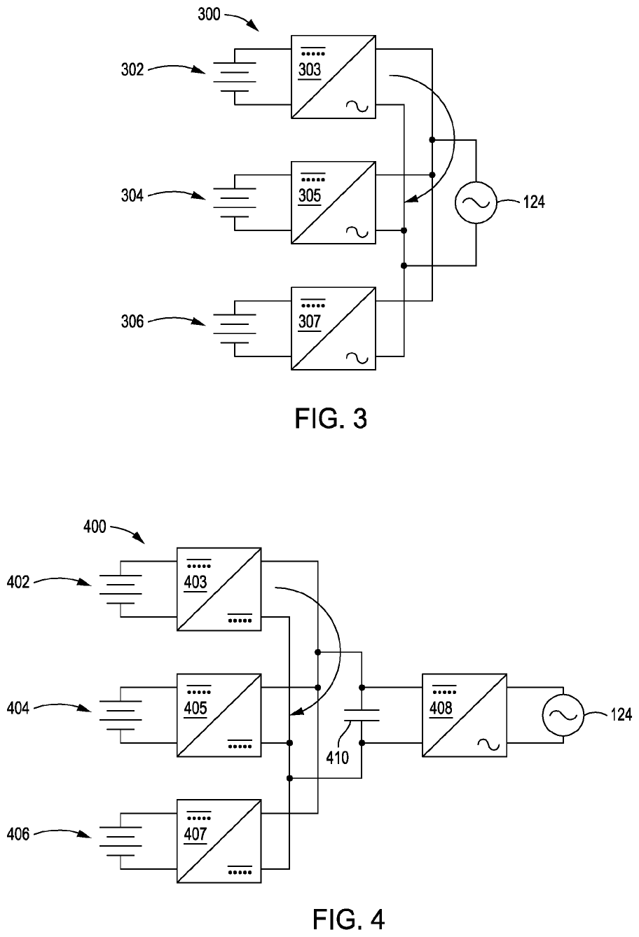

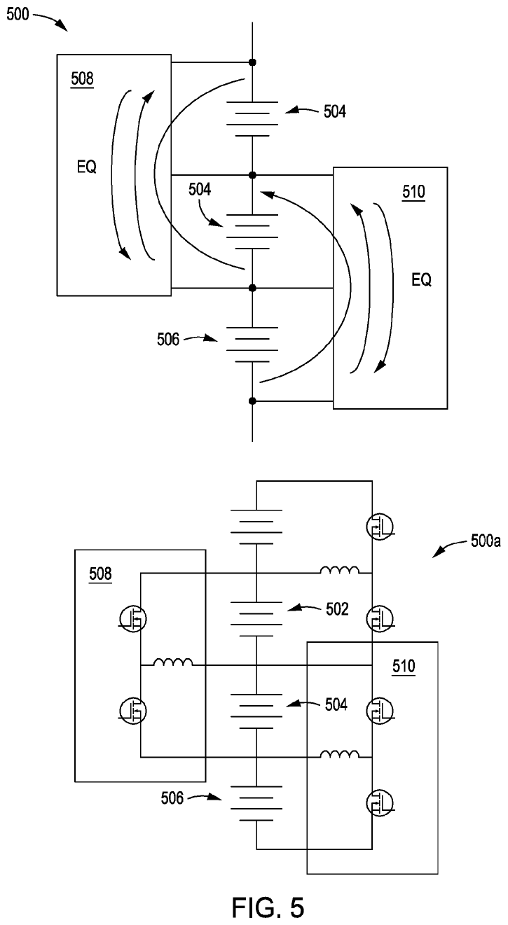

Additionally, the BMU 290 communicates with the DER controller 116 to perform electrochemical impedance spectroscopy (EIS) measurement of one or more batteries and/or battery cells. For example, as noted above, EIS can be configured for use with the a storage system (e.g., the AC battery system 200). For example, FIGS. 3 to 7 are schematic diagrams of electrical circuits, in accordance with at least some embodiments of the present disclosure. EIS can be used at a battery level or at individual cells of a battery. For illustrative purposes, FIGS. 3 and 4 are described in terms of electrochemical impedance spectroscopy (EIS) at a battery level and FIGS. 5-7 are described in terms of electrochemical impedance spectroscopy (EIS) at a battery cell level. The electrical circuits described herein are configured to provide long steady state periods for taking accurate EIS measurements of one or more batteries and provide injection of current and/or voltage at varying (non-grid) frequencies. For example, as noted above, with respect to a storage system with 2 or more batteries, a battery under test can be held at steady state (likely, but not necessarily, zero current) and the remaining batteries are configured to respond to the operational demand placed on a storage system. Thus, if a storage system cannot respond with n−1 batteries (e.g., the battery under test), the EIS measurement would be interrupted. One or more other components of the system 100 can be used in conjunction with a battery under test to allow a long, accurate EIS measurement of the battery under test. For example, the one or more components may end up operating in a way that would be ideal for an n−1 battery system rather than the n battery system. For example, in at least some embodiments, such as when the system 100 comprises a forecasting function, a time in which n−1 batteries can satisfy the system performance could be forecasted and the EIS measurement be duly scheduled. In addition to responding to the operational demands placed upon a battery system, the additional batteries (or other devices in the larger system) could cancel-out the frequencies induced by the EIS measurement. Additionally, in at least some embodiment, e.g., when EIS measurements of two batteries are taken simultaneously, the measurements could be made at the same frequencies but with a phase shift of 180 degrees so that the two batteries would cancel out each other's frequencies induced by the EIS measurements, and the n−2 batteries would continue responding to the demands placed upon the battery system.

FIG. 3 illustrates an electrical circuit 300 comprising three parallel coupled AC batteries (the battery 130), e.g., a battery 302, battery 304, and a battery 306, coupled to a corresponding DC to AC converter, e.g., a DC to AC converter 303, a DC to AC converter 305, and a DC to AC converter 307. For example, during the EIS measurement, power between the batteries is configured to be exchanged across a power grid (e.g., the grid 124). For example, during the EIS measurement the battery 302 is connected to the battery 304 so that the battery 304 can provide power to the battery 302, and the frequencies are canceled out to not cause power line interference. In at least some embodiments, the battery 302 can be connected to the battery 306 instead of the battery 304. A system controller (the DER controller 116) is configured to initiate an EIS measurement. When this EIS measurement is initiated, the system controller is configured to command a battery under EIS measurement to cease responding to local grid demands. For example, a BMU (e.g., the BMU 190) on the battery under EIS measurement is configured to command the BMU associated inverters/converters to modulate the associated inverters/converters power electronic to create EIS perturbations while the BMU takes current and voltage measurements. In at least some embodiments, the EIS perturbations may need to exchange energy from an outside source, such as the grid, another battery, or one or more PVs. At least a portion of the remaining batteries not under test will continue to respond to local grid commands while simultaneously canceling out any energy required for the EIS measurement. The battery under EIS measurement indicates to the system controller when the battery under EIS measurement finishes EIS measurement. The system controller then returns the system to normal operation, including the battery that finished EIS measurement. In at least some embodiments, the system controller may also interrupt EIS measurements if the demands on the local grid system require the response of the battery under EIS measurement.

FIG. 4 illustrates an electrical circuit 400 comprising three parallel coupled DC batteries, e.g., a battery 402, battery 404, and a battery 406, coupled to a corresponding DC to DC converter, e.g., a DC to DC converter 403, a DC to DC converter 405, and a DC to DC converter 407. For example, during the EIS measurement, power between the batteries is configured to be exchanged across a power grid (e.g., the grid 124). For example, during the EIS measurement the battery 402 is connected to the battery 404 so that the battery 404 can provide power to the battery 402 at the DC bus. In at least some embodiments, the frequencies are canceled out at the DC bus to not cause power line interference. Alternatively or additionally, a DC-AC converter 408 and a capacitor 410 can force the ripple onto the dc bus to prevent frequencies from creating grid interference.

FIG. 5 illustrates an electrical circuit 500 comprising three series-coupled DC batteries (e.g., a battery 502, battery 504, and a battery 506) and battery-to-battery equalizers (e.g., an equalizer 508 and an equalizer 510 (see electrical circuit 500a, for example). Similar to the electrical circuit 400, the (appropriately rated, 2× full current for full output current) converters in a series connected system can provide full control of the current for a battery under test. The battery under measurement can be held at steady state (likely, but not necessarily, zero current) by the series connected equalizers. Likewise, AC perturbation can be provided by the n−1 batteries not under measurements.

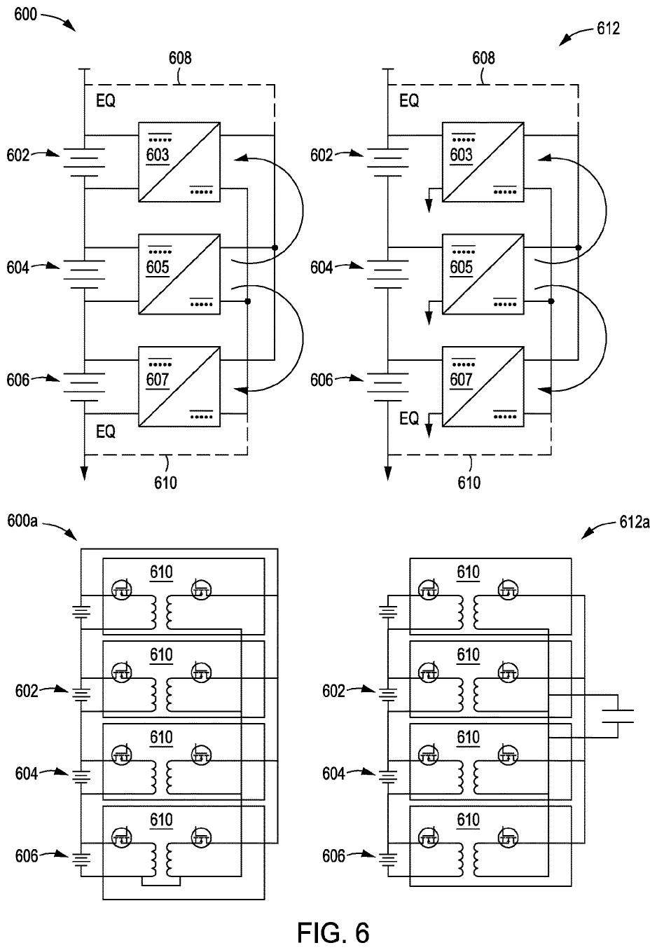

FIG. 6 illustrates an electrical circuit 600 comprising series-coupled DC, battery-to-bus equalizers. For example, similar to the electrical circuit 500, the electrical circuit 600 comprises parallel equalizers (see electrical circuit 600a, for example). For example, a battery 602, a battery 604, and a battery 606 can be connected in series to each other and to a DC to DC converter 603, a DC to DC converter 605, and a DC to DC converter 607, respectively. Battery to bus equalizer 608 and battery to bus equalizer 610 can be connected across the battery 602, the battery 604, the battery 606 and the DC to DC converter 603, the DC to DC converter 605, and the DC to DC converter 607. Alternatively, a parallel configuration 612 comprising battery to bus equalizer 608 and battery to bus equalizer 610 can also be used (see electrical circuit 612a, for example). For example, converters are, typically, connected in parallel without connecting to a main bus, sometimes referred to as a virtual bus. Thus, the capacitor is configured to provide a small amount of energy storage to facilitate the exchange of energy.

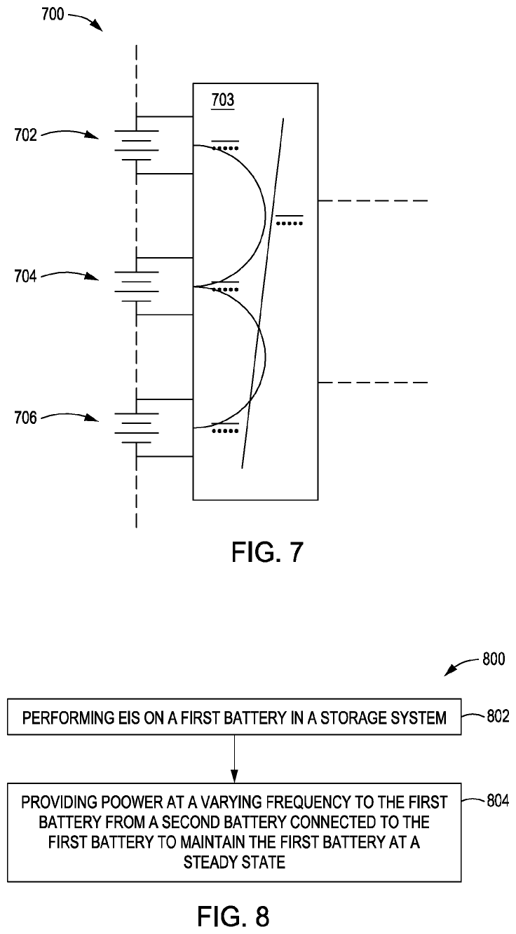

FIG. 7 illustrates an electrical circuit 700 comprising multi-input converters/inverters or equalizers 703 that connect to a battery 702, a battery 704, and a battery 706. When multi-input converters are used, one or more combinations battery and converters/inverters or equalizers 703 can be used. For example, the battery can be independent or in series or the converters/inverters may have an output or may be configured in a similar fashion to the single-input equalizers.

With any of the circuits described herein, perturbation can be provided by a linear circuit (not shown). For example, instead of relying on switching power converters to provide perturbations, a linear circuit may be used, which may provide better control of the perturbations. As a linear load needs a DC-bias to provide both polarities to create a sinusoidal wave, the other n−1 converters in the storage system can handle the operational demand and provide current to cancel the DC bias created by the linear circuit. Alternatively or additionally, an auxiliary switching converter can be used for perturbations. For example, similar to the linear circuit, a specialized switching converter can be configured to provide more accurate perturbations for EIS measurements. The auxiliary converter can be configured to operate in parallel to the main converter. Alternatively or additionally, a housekeeping power supply can supply circuits to operate a power converter (e.g., the multi-input converters/inverters or equalizers 703) that can be configured to also create perturbations for EIS measurements.

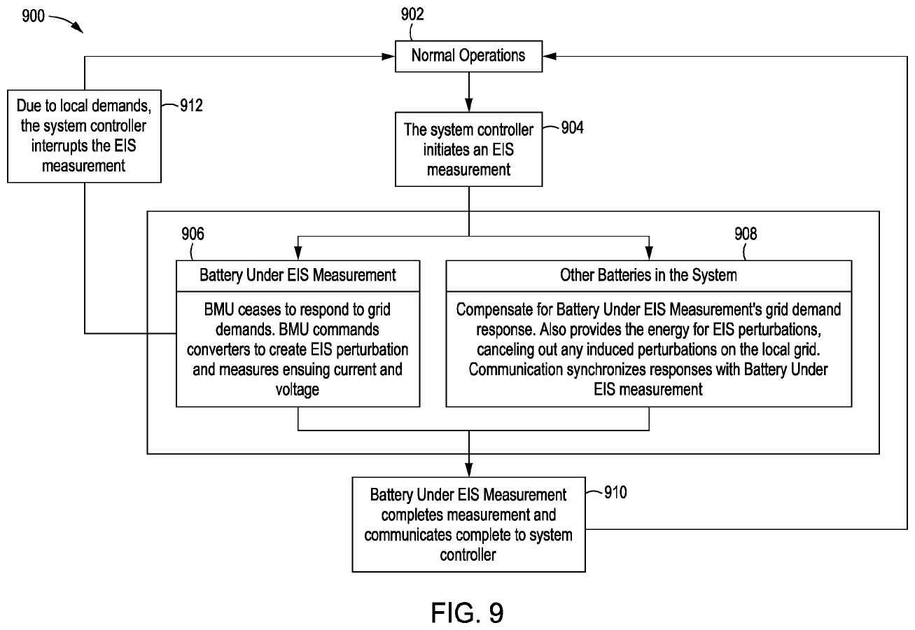

FIGS. 8 and 9 are flowcharts of a method 800/900 for taking EIS measurements in a storage system, in accordance with at least some embodiments of the present disclosure. For example, initially, the system 100 can be running under normal operation conditions, e.g., see 902 of FIG. 9. Next, at 802, the method 800 comprises performing EIS on a first battery in a storage system. For example, the system controller initiates an EIS measurement (see 904). In at least some embodiments, the EIS can be performed periodically to collect data that helps to predict the SoH (state of health) of the battery. The data may be gathered and brought to a cloud server for fleet-wide analysis.

Next, at 804, the method 800 comprises providing power at a varying frequency to the first battery from a second battery connected to the first battery to maintain the first battery at a steady state. For example, the BMU connected to the battery under EIS measurement ceases to respond to grid demands. For example, the BMU commands the converters of the battery under EIS measurement to create EIS perturbations and measures the ensuing current and voltage (see 906). Similarly, the other batteries in the system 100 compensate for the battery under EIS measurement's grid demand response (see 908). The other batteries in the system 100 also provides the energy for the EIS perturbations, thus canceling out any induced perturbations on the local grid. During such time, communication synchronizes response with the battery under EIS measurement.

804 is continued until the battery under EIA measurement completes the measurement (see 910), at which time the BMU communicates to the system controller that the measurement is complete, and the system controllers returns to normal operation (e.g., see 902).

Conversely, during 804, if the system controller determines that the local grid demands more power than the other batteries in the system 100 can provide, the system 100 can temporarily interrupt the EIS measurement (see 912) and return to normal operation (e.g., see 902).

While the foregoing is directed to embodiments of the present disclosure, other and further embodiments of the disclosure may be devised without departing from the basic scope thereof, and the scope thereof is determined by the claims that follow.

1. A method for taking electrochemical impedance spectroscopy (EIS) measurements in a storage system, comprising:
performing EIS on a first battery in the storage system; and
providing power at a varying frequency to the first battery from a second battery connected to the first battery to maintain the first battery at a steady state.

2. The method of claim 1, wherein performing EIS is done periodically to collect data for predicting a state of health (SoH) of the first battery.

3. The method of claim 2, wherein the data is gathered and brought to a cloud server for fleet-wide analysis.

4. The method of claim 1, wherein performing EIS is done when the first battery ceases to respond to grid demands.

5. The method of claim 1, wherein performing EIS comprises commanding converters of the first battery to create EIS perturbations and measure an ensuing current and voltage.

6. The method of claim 1, further comprising compensating a grid demand response for the first battery using the second battery, wherein the second battery provides the energy for the EIS perturbations thereby canceling out any induced perturbations on the grid.

7. The method of claim 1, further comprising continuing performing EIS on the first battery until the first battery completes the EIS, communicating to a system controller that the EIS is complete, and returning to normal operation.

8. A non-transitory computer readable storage medium having instructions stored thereon that when executed by a processor perform a method for taking electrochemical impedance spectroscopy (EIS) measurements in a storage system comprising:
performing EIS on a first battery in the storage system; and
providing power at a varying frequency to the first battery from a second battery connected to the first battery to maintain the first battery at a steady state.

9. The non-transitory computer readable storage medium of claim 8, wherein performing EIS is done periodically to collect data for predicting a state of health (SoH) of the first battery.

10. The non-transitory computer readable storage medium of claim 9, wherein the data is gathered and brought to a cloud server for fleet-wide analysis.

11. The non-transitory computer readable storage medium of claim 8, wherein performing EIS is done when the first battery ceases to respond to grid demands.

12. The non-transitory computer readable storage medium of claim 8, wherein performing EIS comprises commanding converters of the first battery to create EIS perturbations and measure an ensuing current and voltage.

13. The non-transitory computer readable storage medium of claim 8, further comprising compensating a grid demand response for the first battery using the second battery, wherein the second battery provides the energy for the EIS perturbations thereby canceling out any induced perturbations on the grid.

14. The non-transitory computer readable storage medium of claim 8, further comprising continuing performing EIS on the first battery until the first battery completes the EIS, communicating to a system controller that the EIS is complete, and returning to normal operation.

15. An energy management system, comprising:
a controller configured to:
perform electrochemical impedance spectroscopy (EIS) on a first battery in a storage system; and
provide power at a varying frequency to the first battery from a second battery connected to the first battery to maintain the first battery at a steady state.

16. The energy management system of claim 15, wherein the controller is further configured to perform EIS done periodically to collect data for predicting a state of health (SoH) of the first battery.

17. The energy management system of claim 16, wherein the data is gathered and brought to a cloud server for fleet-wide analysis.

18. The energy management system of claim 15, wherein the controller is further configured to perform EIS when the first battery ceases to respond to grid demands.

19. The energy management system of claim 15, wherein the controller is further configured to command converters of the first battery to create EIS perturbations and measure an ensuing current and voltage.

20. The energy management system of claim 15, wherein the controller is further configured to compensate a grid demand response for the first battery using the second battery, wherein the second battery provides the energy for the EIS perturbations thereby canceling out any induced perturbations on the grid.
